(19) United States
(12) Patent Application Publication
(10) Pub. No.: US 2019/0327001 A1
(43) Pub. Date: Oct. 24, 2019

(54) OPTICAL LINKING OF SERVER CHASSIS

(71) Applicant: HEWLETT PACKARD ENTERPRISE DEVELOPMENT LP, Houston, TX (US)

(72) Inventors: Harvey Edward White, JR., Houston, TX (US); Gerald K. Kleyn, Houston, TX (US)

(21) Appl. No.: 15/958,852

(22) Filed: Apr. 20, 2018

(51) Int. Cl. H04B 10/80; H05K 7/14; H05K 7/20

(52) U.S. Cl. CPC H04B 10/801; H05K 7/1452; H05K 7/1492; H05K 7/20836; H05K 7/20736

(57) ABSTRACT

A system includes a first server including a first optical communication system and a first control system, and a second server including a second optical communication system and a second control system. The first and second control systems optically communicates with each other using the first and second optical communication systems, and the second control system is configured to control a temperature of the first and second servers by controlling airflow from the first server to the second server.

### BACKGROUND

The growth of the Information Technology sector in the economy has led providers of online information and services, in-house enterprise data management groups, government agencies and others to establish high-volume data processing centers, also known as server farms, to process, manage and store large amounts of information. The increased demand for bandwidth, processing power, storage capacity and reliability has resulted in high-density computational platforms and architectures, such as blade servers installed in standardized rack enclosures and assembled into server towers.

The description provided in the background section should not be assumed to be prior art merely because it is mentioned in or associated with the background section. The background section may include information that describes one or more aspects of the subject technology.

### SUMMARY

In certain aspects, a system is described that includes a first server including a first optical communication system and a first control system, and a second server including a second optical communication system and a second control system. The first and second control systems optically communicate with each other using the first and second optical communication systems, and the second control system is configured to control a temperature of the first and second servers by controlling airflow from the first server to the second server.

In certain aspects, a method is described that includes deploying a first server and a second server in a network. The first server includes a first optical communication system and a first control system, and the second server includes a second optical communication system and a second control system. The method also includes transmitting, using the first control system, a detection signal to the second control system through the first optical communication system, receiving, using the first control system, an acknowledgement signal from the second control system through the first optical communication system, and controlling, using one of the first and second control systems, a temperature of the first and second servers by controlling airflow from the first server to the second server.

In certain aspects, a system is described that includes a first server including a first optical communication system and a first control system, and a second server including a second optical communication system and a second control system. The first control system includes a non-transitory, computer-readable medium readable by a processor of the first server and storing computer-readable instructions that when executed by the processor configures the first control system to transmit, using the first control system, a detection signal to the second control system through the first optical communication system, receive, using the first control system, an acknowledgement signal from the second control system through the first optical communication system, and control, using one of the first and second control systems, a temperature of the first and second servers by controlling airflow from the first server to the second server.

In certain aspects, a first control system is described that transmits a detection signal to a second control system through a first optical communication system and receives an acknowledgement signal from the second control system through the first optical communication system. The first control system controls a temperature of a first server including the first control system and a second server including the second control system by controlling airflow from the first server to the second server.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments. In the drawings.

FIG. 1 illustrates a back-to-back configuration including a first server and a second server.

FIG. 2 is a schematic view of the rear portion of the servers of FIG. 1, according to embodiments disclosed.

FIG. 3 is a schematic top view of the servers of FIG. 1 installed in the back-to-back configuration, according to embodiments disclosed.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

The detailed description set forth below is intended as a description of various implementations and is not intended to represent the only implementations in which the subject technology may be practiced. As those skilled in the art would realize, the described implementations may be modified in various different ways, all without departing from the scope of the present disclosure. Accordingly, the drawings and description are to be regarded as illustrative in nature and not restrictive.

The disclosed system provides an improvement to computer functionality by allowing two or more servers to communicate with each other. Specifically, the disclosed system provides optical communication between two severs installed on a server rack or any other suitable framework for holding the servers in a back-to-back configuration. Using the optical communication system, the servers may exchange operating information including, for example, thermal information, total power consumption, power capping information, and the like. Based on the information exchanged, cooling air flowing through the servers may be controlled by controlling the fan speeds (i.e., the fan rotational speed) of the servers.

For the purposes of discussion, “cooling air”, or variations thereof, refer to air that is used to dissipate heat from the servers. From the discussion below, it will thus be understood that the cooling air may not always refers to air that is cool, but may also refer to heated air used by the servers to dissipate heat.

For the sake of discussion, embodiments disclosed are directed to managing the airflow between two servers in a back-to-back configuration. However, the embodiments are not limited to managing airflow through servers. The airflows(s) through any number of air-cooled systems or devices in any configuration can be managed using the principles disclosed herein.

To increase processor and memory density, and improve server rack space density, servers may be mounted on the server rack in a back-to-back configuration. In this configuration, the backs (or rear portions) of two servers may face each other when the servers are mounted or otherwise installed in the rack. In order to provide effective cooling for dissipating heat generated by the electrical circuits of the server, each server may control inlet fan speed to control the amount of cooling air flowing through the server. The fan speed may be controlled (increased or decreased) based on the internal temperature of the server, which depends on the heat generated by the electrical circuits of the server. The operating efficiency of the server may be improved by operating the fan(s) based on the temperature of the server.

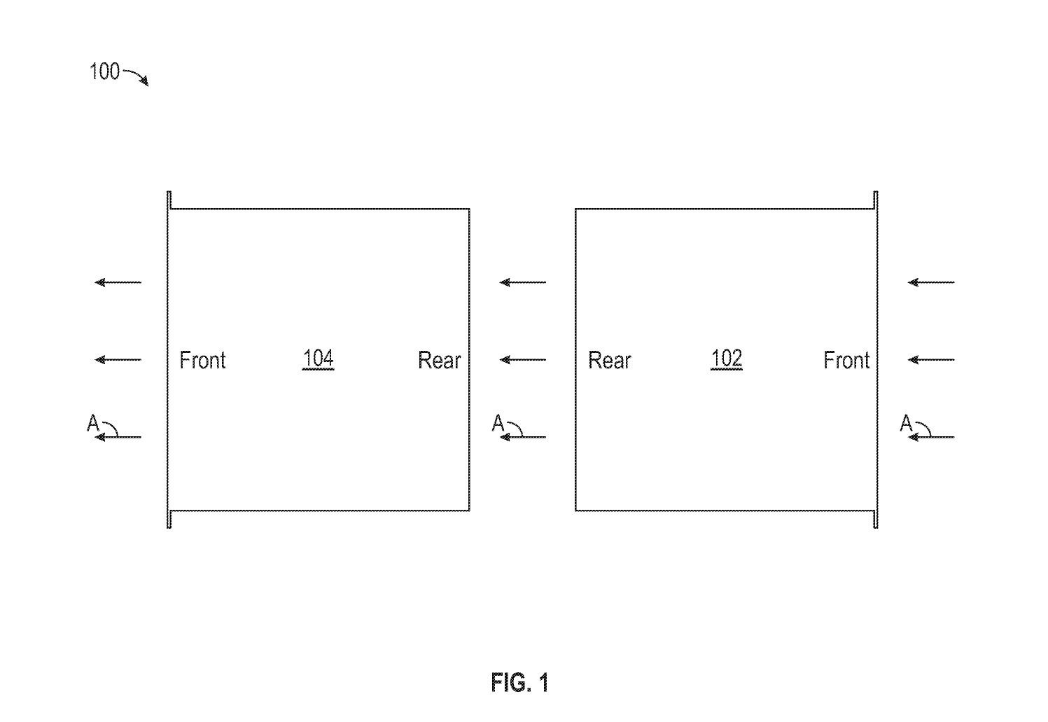

A back-to-back configuration of servers in the rack may result in the cooling air for both servers being different. FIG. 1 illustrates a back-to-back configuration 100 including a first server 102 and a second server 104. The flow of air through the first and second server 102 and 104 is generally indicated by arrows A. The cooling air may be drawn by the first server 102 through the front portion thereof and may flow through the first server 102 while dissipating heat generated by the electrical circuits of the first server 102. This may cause the temperature of the air to increase. This heated air is then exhausted by the first server 102 through the rear portion thereof and, because the servers 102 and 104 are placed back-to-back, the second server 104 may receive this heated air for cooling purposes. The second server 104 draws the heated air through the rear portion thereof. However, due to increased temperature of this heated air, an increased airflow of the heated air through the second server 104 may be required to cool the second server 104, which, in turn, may require operating the inlet fan(s) of the second server 104 at a higher speed.

When the second server 104 draws in the heated air at a higher rate, a pressure drop across the first server 102 (from the front to the rear) may increase. Thus, the cooling air drawn into the first server 102 may increase and the first server 102 will experience more cooling than necessary. The first server 102 may therefore reduce the speed of its inlet fan(s). Thus, the amount of cooling air drawn in by the first server 102 is reduced, and, in turn, the heated air exhausted from the first server 102 is reduced. This may force the second server 104 to increase its fan speeds even more to counteract the decreased airflow from the first server 102.

The servers 102 and 104 may each include a control system, also referred to as a platform management system, for controlling the airflow through the respective servers 102 and 104. The control system maintains and reports on the operational state of the respective server. The control system may be a separate subsystem that may operate independent of the main system (e.g., the main processors) of the server. The parameters that are typically controlled and monitored by the control system may include the fan types or configurations and fan speed, server power consumption, server temperature, health/operating state of the critical electrical components (e.g., primary processors, memory devices), and the like.

It may be beneficial for the control systems of the servers 102 and 104 to communicate the temperature, fan speed, and other information with each other, and control the fans and, thereby the cooling air, based on the information. Connecting the control systems using cables can be cumbersome since the cables have to be run in tight spaces in the rack. In addition, technicians may forget to connect the cables to the servers 102 and 104. A solution is to use blind-mate connectors installed, for instance, on a back panel between the servers 102 and 104 on the rack. The servers 102 and 104 connect to the corresponding blind-mate connectors as the servers 102 and 104 are installed in the rack. However, if the servers 102 and 104 are large, or if the installation process is performed correctly, the connectors could be damaged or may not properly mate with the servers, resulting in a poor connection or no connection at all.

According to embodiments disclosed, the control systems of the servers 102 and 104 communicate optically. By using optical communication, the servers 102 and 104 (and more specifically, the control systems thereof) can be reliably connected to each other.

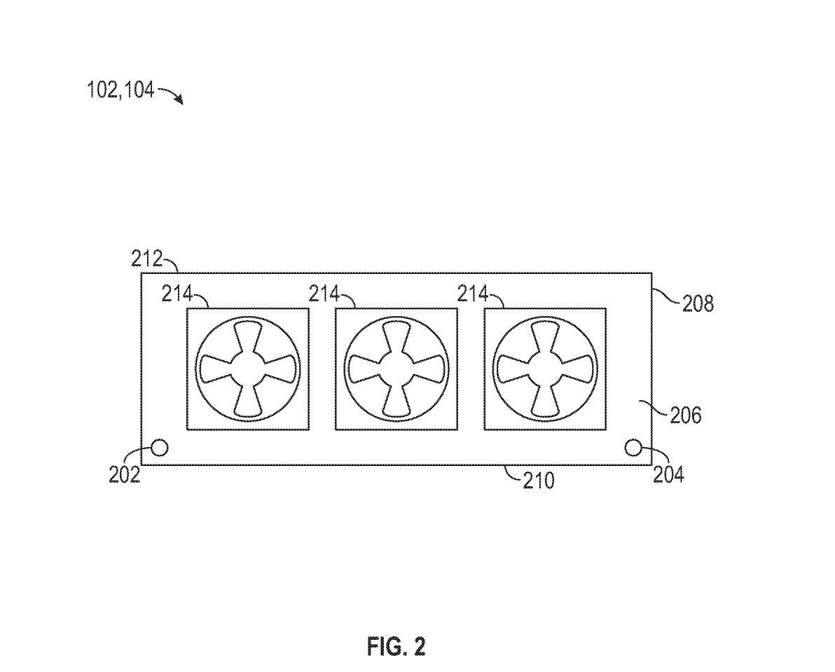

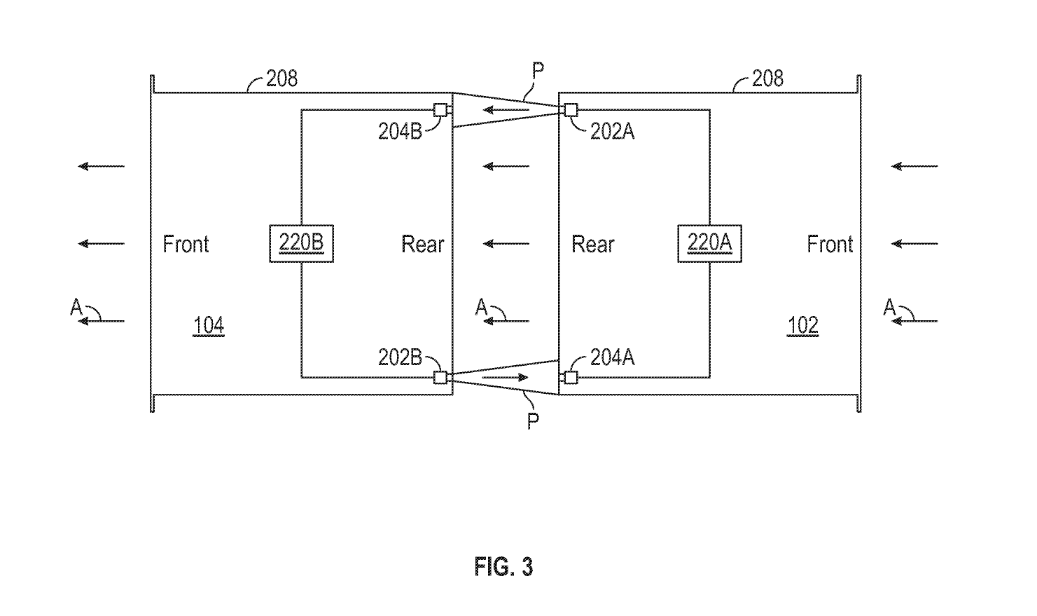

FIG. 2 is a schematic view of the rear portion of either server 102 or 104, according to embodiments disclosed. As illustrated in FIG. 2, each server 102 and 104 includes an optical communication system including an optical transmitter 202 and an optical receiver 204 located on back panel 206 of the server chassis 208. In an example, and as illustrated, the optical transmitter 202 and the optical receiver 204 are located at opposite corners of the back panel 206. However, the location of the optical transmitter 202 and the optical receiver 204 is not limited in this regard. The optical transmitter 202 and the optical receiver 204 can be at any location on the back panel 206 provided they are equally spaced from the center of the chassis 208 and are located the same distance from the bottom edge 210 or the top edge 212 of the chassis 208. Thus, when the servers 102 and 104 are installed in the back-to-back configuration (FIG. 3), the optical transmitter 202 of server 102 faces the optical receiver 204 of server 104 and the optical receiver 204 of server 102 faces the optical transmitter 202 of the server 104. The back panel 206 includes three fans 214, which may be either exhaust fans or inlet fans, depending on the placement of the servers 102 and 104 in the back-to-back configuration. For instance, the fans 214 of the server 102 are exhaust fans if the server 102 is the “front” server, while the fans 214 of the server 104 are inlet fans if the server 104 is the “rear” server. Although FIG. 2 illustrates three fans 214, the number of fans 214 is not limited in this regard. In some embodiments, the fans 214 may be dual-purpose fans that may be operated both as inlet or exhaust fans.

FIG. 3 is a schematic top view of the servers 102 and 104 installed in the back-to-back configuration, according to embodiments disclosed. For the sake of discussion, the optical transmitter and optical receiver of the server 102 are indicated as optical transmitter 202A and optical receiver 204A, and the optical transmitter and optical receiver of the server 104 are indicated as optical transmitter 202B and optical receiver 204B.

The optical transmitters 202A, 202B may be or include an infrared light-emitting diode (LED) to emit infrared radiation P. However, the type of radiation is not limited in this regard. The infrared radiation may be transmitted as a stream of pulses. The optical receivers 204A, 204B may be or include a photodiode to convert the received infrared radiation to an electric current (or signal). In an example and as illustrated, the infrared radiation P may be emitted in a cone-shape pattern. Such a pattern of the infrared radiation may allow for communication between the optical transmitters 202A, 202B and the optical receiver 204A, 204B if there is misalignment between the server chassis 208 when the servers 102 and 104 are installed in the rack. It should be noted that the cone-shaped pattern is merely an example, and any shape or pattern that may permit communication between the optical transmitters 202A, 202B and the optical receiver 204A, 204B when there is a misalignment between the servers 102 and 104 may be used. Each server 102 and 104 may include a respective control systems (platform management systems) 220A and 220B communicatively coupled to the respective optical transmitters 202A and 202B and optical receivers 204A and 204B.

The control systems 220A and 220B may be implemented with one or more processors. The processor can be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable entity that can perform calculations or other manipulations of information. The processor may be communicably coupled to a memory such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device for storing information and instructions to be executed by the processor. The instructions may be stored in the memory and implemented in one or more computer program products, i.e., one or more modules of computer-readable instructions encoded on a computer readable medium for execution by, or to control the operation of, the control systems 220A and 220B, and according to any method well known to those of skill in the art, including, but not limited to, computer languages such as data-oriented languages (e.g., SQL, dBase), system languages (e.g., C, Objective-C, C++, Assembly), architectural languages (e.g., Java, .NET), and application languages (e.g., PHP, Ruby, Perl, Python).

When the servers 102 and 104 are installed in the back-to-back configuration and turned ON, the control system 220A of the server 102 may transmit a detection signal via the optical transmitter 202A and monitor for an acknowledgement signal from the server 104. The detection signal may be transmitted at regular intervals (e.g., 1 second) until the acknowledgement signal is received from the server 104. The control system 220B of server 104 may receive the detection signal via the optical receiver 204B and provide the acknowledgment signal via the optical transmitter 202B. The acknowledgment signal may be received by the control system 220A via the optical receiver 204A. Additionally or alternatively, the control system 220B of the server 104 may transmit a detection signal (e.g., every 1 second) via the optical transmitter 202B and monitor for an acknowledgment signal from the server 102 received at the optical receiver 204B. The control system 220A may receive the detection signal via the optical receiver 204A and provide the acknowledgement signal via the optical transmitter 202A.

When the servers 102 and 104 detected each other, the optical transmitters 202A and 202B are optically coupled to the corresponding optical receivers 204A and 204B and communication may be established between the servers 102 and 104 (specifically, between the control system 220A and 220B). Both servers 102 and 104 may exchange cooling system configuration that includes information about the mechanical components of the servers 102 and 104 that may affect the airflow through the corresponding chassis 208. This information may include, for instance, the air input/output capacity of one or more fans 214 of the servers 102 and 104, rotational speed of one or more fans 214, number of fans, dimensions of the chassis 208, and the like. Based on the cooling system configuration, the control systems 220A and/or 220B determine whether the servers 102 and 104 are compatible with each other. For instance, in determining compatibility, the control systems 22A and/or 220B may check if the air intake/output capacities and rotational speeds of the fans 214 of server 102 are similar (or within a certain difference) to that of the fans 214 of server 104. In other instances, the control systems 22A and/or 220B may check if the dimensions of chassis 208 of server 102 are similar (or within a certain difference) of that of chassis 208 of server 104. If incompatible, then the server startup process is interrupted and the servers 102 and 104 are turned OFF. For instance, the control systems 220A and 220B may signal the server control system to shut down the servers 102 and 104. Because the startup process is interrupted, software applications (e.g., system configuration files, utility programs, etc.) that may typically be loaded to bring the servers 102 and 104 to an operating state/configuration may not be loaded. The control systems 220A and/or 220B may send a message (e.g., an alarm) to the operator to indicate the incompatibility between the servers 102 and 104. Once it is confirmed that the components are compatible with each other, the servers 102 and 104 may complete the start-up process and attain an operating state.

The control system 220A and 220B may then exchange temperature information that may be obtained using temperature sensors included in the servers 102 and 104. For effective thermal management, it is desirable for the server receiving the hottest air for cooling purposes to control the fan speeds of the other server(s). This may ensure that all servers are adequately cooled as the fans speeds for all servers are set to be the same. Thus, in the back-to-back configuration illustrated in FIG. 3, control system 220B of server 104 may control the fan speed of the server 102 since server 104 receives hotter air compared to server 102. In this regard, the server 104 may be referred to as the “active” server, while the server 102 may be referred to as the “passive” server.

The control system 220B may transmit a fan speed control signal to the control system 220A to indicate a desired fan speed of the fan(s) of the server 102. The fan speed control signal may be transmitted using the optical communication link established between the optical transmitter 202B and optical receiver 204A. The control system 220B may issue an acknowledgment via the optical communication link established between the optical transmitter 202A and optical receiver 204B. In an example, the fan speed may be set such that adequate air is exhausted from the server 102 for use by the server 104 for cooling. In another example, if the server 104 requires more cooling air, the server 104 may request for the fan speed of the server 102 to be increased so that more air is exhausted from the server 102. As mentioned above, when a pressure drop across the first server 102 increases, more cooling air is drawn into the first server 102 and the first server 102 will experience more cooling than necessary. In such situations, the control system 220B may control the speed of the fan(s) of server 102 so that the first server 102 experiences adequate cooling.

The control system 220B may thus control the temperature of the first and second servers 102 and 104 by controlling the airflow from the first server 102 to the second server 104. The control system 220B may receive information about the temperature inside the server 102 and the fan speed control signal may be based on the temperature information. The temperature information may be received at regular intervals, or at times by the control server 220B. By controlling the fan speeds, power consumption of the servers 102 and 104 may be decreased. Additionally, noise generated by the fans is decreased.

In the event of a fan failure, the failure may be communicated to control systems 220A and 220B and fan control may be modified so that proper cooling is maintained. This may include increasing the speed of the one or more fans to compensate for the airflow lost by the failed fan.

In addition to communicating the fan speeds and thereby control the airflow through the servers 102 and 104, other parameters that may be communicated between the control systems 220A and 220B may include total power consumption and power capping information for allowing the total power consumption of the servers 102 and 104 to be limited to a threshold level. Depending on workloads, the control systems 220A and 220B operative cooperatively to enable maximum performance of each server while maintaining total power consumption at or under the threshold level. This is accomplished by communicating total workload demands to both control systems 220A and 220B, and when the workload on one of the servers decreases, the power cap (e.g., the threshold level) is relaxed on the server that is heavily loaded.

As used herein, the phrase “at least one of” preceding a series of items, with the terms “and” or “or” to separate any of the items, modifies the list as a whole, rather than each member of the list (e.g., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. No claim element is to be construed under the provisions of 35 U.S.C. § 112, sixth paragraph, unless the element is expressly recited using the phrase “means for” or, in the case of a method claim, the element is recited using the phrase “step for”.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language claims and to encompass all legal equivalents. Notwithstanding, none of the claims are intended to embrace subject matter that fails to satisfy the requirements of the applicable patent law, nor should they be interpreted in such a way.

1. A system, comprising:
a first server including a first optical communication system and a first control system; and
a second server including a second optical communication system and a second control system, the first and second control systems optically communicating with each other using the first and second optical communication systems, and at least the second control system configured to control a temperature of the first and second servers.

2. The system of claim 1, wherein the first optical communication system includes a first optical transmitter and a first optical receiver and the second optical communication system includes a second optical transmitter and a second optical receiver.

3. The system of claim 2, wherein the first server and the second server are arranged in a back-to-back configuration such that the first optical transmitter and the second optical receiver are optically coupled to each other and the second optical transmitter and the first optical receiver are optically coupled to each other.

4. The system of claim 3, wherein the first and second optical transmitters are configured to emit radiation having a pattern that permits optical coupling when there is misalignment between the first and second servers.

5. The system of claim 4, wherein the first and second optical transmitters are configured to emit infrared radiation having a cone-shaped pattern.

6. The system of claim 3, wherein the first and second control systems exchange cooling system configuration to determine compatibility between the first and second servers.

7. The system of claim 6, the cooling system configuration includes information on one or more of air intake/output capacity of one or more fans of the first and second servers, a rotational speed of one or more fans of the first and second servers, number of fans, and dimensions of server chassis of the first and second servers.

8. The system of claim 1, wherein the second control system is configured to control rotational speed of one or more fans of the first server based on the temperature of the first and second servers.

9. The system of claim 1, wherein the first and second optical communication systems are disposed on a back panel of the respective first and second servers.

10. A method, comprising
deploying a first server and a second server in a network, wherein
the first server includes a first optical communication system and a first control system, and the second server includes a second optical communication system and a second control system;
transmitting, using the first control system, a detection signal to the second control system through the first optical communication system;
receiving, using the first control system, an acknowledgement signal from the second control system through the first optical communication system; and
controlling, using at least the second control system, a temperature of the first and second servers.

11. The method of claim 10, wherein the first server and the second server are arranged in a back-to-back configuration, and the first optical communication system includes a first optical transmitter and a first optical receiver and the second optical communication system includes a second optical transmitter and a second optical receiver, and the method further comprises:
determining a presence of the first and second servers based on the acknowledgement signal; and
optically coupling the first optical transmitter and the second optical receiver to each other, and the second optical transmitter and the first optical receiver to each other.

12. The method of claim 11, further comprising:
exchanging cooling system configuration between the first and second servers; and
determining compatibility between the first and second servers based on the cooling system configuration.

13. The method of claim 12, wherein exchanging cooling system configuration comprises exchanging information including one or more of air intake/output capacity of one or more fans of the first and second servers, a rotational speed of one or more fans of the first and second servers, number of fans, and dimensions of server chassis of the first and second servers.

14. The method of claim 10, wherein the first and second servers are installed in a back-to-back configuration and the second server receives cooling air from the first server.

15. A system, comprising:
a first server including a first optical communication system and a first control system;
a second server including a second optical communication system and a second control system, the first control system including a non-transitory, computer-readable medium readable by a processor of the first server and storing computer-readable instructions that when executed by the processor configures the first control system to:
transmit, using the first control system, a detection signal to the second control system through the first optical communication system;
receive, using the first control system, an acknowledgement signal from the second control system through the first optical communication system; and
control, using at least the second control system, a temperature of the first and second servers.

16. The system of claim 15, wherein the first server and the second server are arranged in a back-to-back configuration, and the first optical communication system includes a first optical transmitter and a first optical receiver and the second optical communication system includes a second optical transmitter and a second optical receiver, and wherein executing the instructions further configures the first control system to:
determine a presence of the second server based on the acknowledgement signal; and
optically couple the first optical transmitter and the second optical receiver to each other, and the second optical transmitter and the first optical receiver to each other.

17. The system of claim 16, wherein executing the instructions further configures the first control system to actuate the first and second optical transmitters to emit radiation having a pattern that permits optical coupling when there is misalignment between the first and second servers.

18. The system of claim 15, wherein executing the instructions further configures the first control system to:
exchange cooling system configuration between the first and second servers; and
determine compatibility between the first and second servers based on the cooling system configuration.

19. The system of claim 15, wherein executing the instructions further configures the first control system to:
exchange cooling system configuration including one or more of air intake/output capacity of one or more fans of the first and second servers, a rotational speed of one or more fans of the first and second servers, number of fans, and dimensions of server chassis of the first and second servers.

20. The system of claim 15, wherein the first and second servers are installed in a back-to-back configuration and the second server receives cooling air from the first server.
